(19) United States
(12) Patent Application Publication
(10) Pub. No.: US 2004/0027261 A1
(43) Pub. Date: Feb. 12, 2004

(54) Centrally synchronized distributed switch

(76) Inventors: Kevin Bruce Tymchuk, Vancouver (CA); Gordon Oliver, Belcarra (CA); Jeff D. Dillabough, Belcarra (CA)

Correspondence Address: Clifford W. Vermette, Vermette & Co., Box 40, Granville Square, Suite 230, 200 Granville Street, Vancouver, BC, V6C 1S4, CA

(21) Appl. No.: 10/387,445

(22) Filed: Mar. 14, 2003

Related U.S. Application Data
(60) Provisional application No. 60/364,090, filed on Mar. 15, 2002.

(51) Int. Cl. H03M 1/48

(52) U.S. Cl. 341/111

(57) ABSTRACT

The present invention comprises a centrally synchronized distributed time-space-time switch fabric wherein connection memory page (CMP) selection information is communicated to remote devices without having to add any extra hardware to the system. The central processor only needs to communicate to the space switch device, and by writing to certain registers in the space switch the processor can control the CMP selection in each of the time switch devices. By providing the page selection information over the same signals that transfer data, these page selection signals do not have to be routed externally or controlled by the distributed software.

### BACKGROUND OF THE INVENTION

When multiple devices are used to create a large time-space-time switch fabric, there must be some mechanism to ensure that changes to the switching configuration are synchronized across all devices. This must be done to ensure that all existing connections are maintained when new connections are added or when old connections are dropped.

Existing solutions require the use of an external hardware pin on each device in the switch fabric and/or require tight timing control over distributed software. When an external hardware pin is used, this pin specifies which of the two connection memory pages (CMP) are to be used by each device. There must be a common source controlling the connection memory page (CMP) selection for all devices, and the hardware signal must be distributed to every device. When designing large switches, individual devices may be placed on different cards in a rack or on different shelves. In this situation, extra signals must be routed between cards or shelves making the system design even more complex.

When the CMP selection is controlled by software, there is a small window in time in which the software must ensure that all devices in the switch are updated with the new page selection information. Due to the distributed nature of time-space-time switches it is likely that separate software controls the individual devices, especially when these devices are placed on different shelves. Coordinating this distributed software to ensure that all devices are updated together is difficult and makes the software design more complex.

Accordingly, it is an object of the present invention to provide a synchronized switch fabric that utilizes a reduced number of signals for synchronization of switches, devices, cards and/or shelves.

It is a further object of the present invention to provide simplified means for synchronization of a switch fabric that reduces the complexity of the distributed software.

### SUMMARY OF THE INVENTION

The present invention comprises a centrally synchronized distributed time-space-time switch fabric wherein connection memory page (CMP) selection information is communicated to remote devices via an in-band signaling channel made up of overhead bytes in the serial links between the devices (i.e. without having to add any extra hardware to the system). The central processor only needs to communicate to the space switch device, and by writing to certain registers in the space switch the processor can control the CMP selection in each of the time switch devices. By providing the CMP selection information over the same links that transfer data, the CMP selection signals do not have to be routed externally or controlled by the distributed software.

The central processor of the present invention is able to coordinate the timing of the CMP changes in all the devices in the system, such that connections may be added, removed, or re-arranged, without corrupting any of the existing connections. The processor initiates a CMP swap by writing to the registers in the space switch. The new CMP selection information is then distributed to each device in the system and each device aligns the page change with the next frame boundary of the data traffic. This ensures that all devices change their CMP's at the appropriate time with respect to the data traffic and no data is lost.

Overhead bytes in the serial links between the devices are used to carry the CMP selection information. These overhead bytes are protected by a Cyclic Redundancy Check (CRC) to ensure that bit errors on the serial link do not inadvertently cause a device to change pages when it should not. If a CRC error is detected on the CMP selection information contained in the overhead bytes, the receiving device will disregard the CMP selection information.

### BRIEF DESCRIPTION OF THE DRAWINGS

The invention itself both as to organization and method of operation, as well as additional objects and advantages thereof, will become readily apparent from the following detailed description when read in connection with the accompanying drawings wherein:

FIG. 1 is a schematic drawing of a control processor and switch;

FIG. 2 is a schematic drawing of a telecom bus;

FIG. 3 is a schematic drawing of an interconnect bus;

FIG. 4 is a diagram showing overhead bytes for both the telecom bus and interconnect bus formats;

FIG. 5 is a diagram showing the in-band signaling channel message format;

FIG. 6 is a diagram showing the in-band signaling channel header format;

FIG. 7 is a schematic drawing showing frame pulse distribution for a switch fabric comprising four time switches and one space switch; and

FIG. 8 is a timing diagram showing the procedure for initiating a CMP change.

### DETAILED DESCRIPTION OF THE INVENTION

Time-Space-Time Switches

Large switches are comprised of many devices working together to perform the overall switch function. The configuration of each device must be coordinated. In time-space-time switch fabrics, the configuration of each device is a centralized function. To guarantee a non-blocking fabric, existing connections may have to be rearranged when new connections are added. Any changes to the configuration must be applied across all devices simultaneously to ensure hitless transitions.

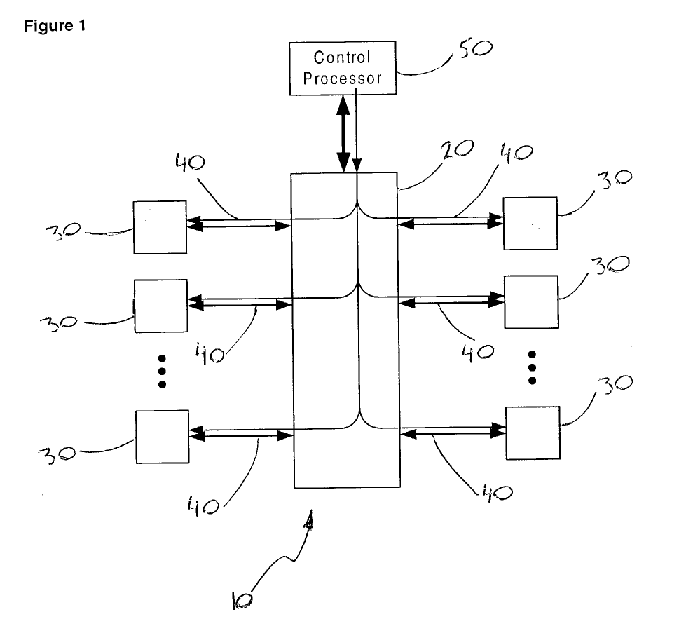

Referring to FIG. 1, the time-space-time switch fabric 10 consists of two types of devices, the space switch device 20 and the time switch devices 30. Each device in the preferred embodiment contains two CMP's, (also referred to as configuration pages) an on-line page and an off-line page. Each device uses the on-line page to perform the switch function, while the off-line page can be programmed with the new switch settings. Once all of the off-line CMP's of all the space switch devices 20 and time switch devices 30 have been programmed with the new switch settings, each device 20, 30 must change between the on-line and off-line pages in a synchronized manner to ensure a hitless transition.

The synchronization of CMP changes is achieved by the use of dedicated overhead bytes in the serial links 40 between the time switch device 20 and space switch devices 30. The control processor 50 communicates directly with the space switch device 20 and communicates indirectly with the time switch devices 30 through the use of these overhead bytes.

The Switch Function

The space switch device 20 and time switch devices 30 can perform switching on a telecom bus or interconnect bus such as the Scaleable Bandwidth Interconnect Bus, made by PMC-Sierra, for interconnection of physical layer devices and link layer devices. Each time switch device 30 is connected to a bus (not shown). The time switch devices 30 switch the incoming data around in time (this is the first time stage) before the data is encoded and transmitted to the space switch device 20 on serial links 40. In the illustrative embodiment the data on the LVDS serial links 40 is 8B/10B encoded, however, other forms of serial links may be used.

In the illustrative embodiment the space switch device 20 recovers the data from up to 32 serial links 40 and decodes the 8B/10B characters. The space switch device 20 then switches the data between the links 40, re-encodes it into 8B/10B characters and transmits the data to the time switch devices 30 via serial links 40. The time switch devices 30 then recover the data, decode the 8B/10B characters and switch the data around in time again (this is the second time stage). The data is then transmitted out of the time switch devices 30 on to the telecom or interconnect bus (not shown).

In the illustrative embodiment the time switch devices 30 are bi-directional. Each device 30 contains two time switches, one for data being sent to the space switch 20 (an input or ingress switch) and one for the data received from the space switch 20 (an output or egress switch). The data flow is from input time switch to the space switch 20, to the output time switch. For any connection, the input and output time switches could be in the same device 30 or in different devices 30, depending on the settings in the space switch 20.

Data Format

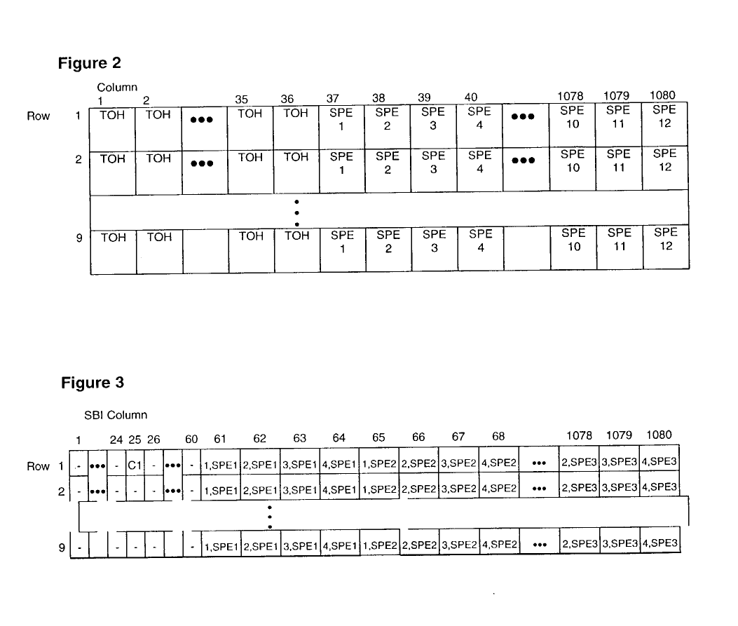

The basic bus structure for the telecom bus is shown in FIG. 2. Columns 1 to 36 contain the transport overhead bytes. Columns 37 to 1080 contain the synchronous payload envelope data.

The bus structure for the interconnect bus is very similar to the telecom bus and is shown in FIG. 3. Columns 1 to 60 contain overhead and columns 61 to 1080 contain the synchronous payload envelope data.

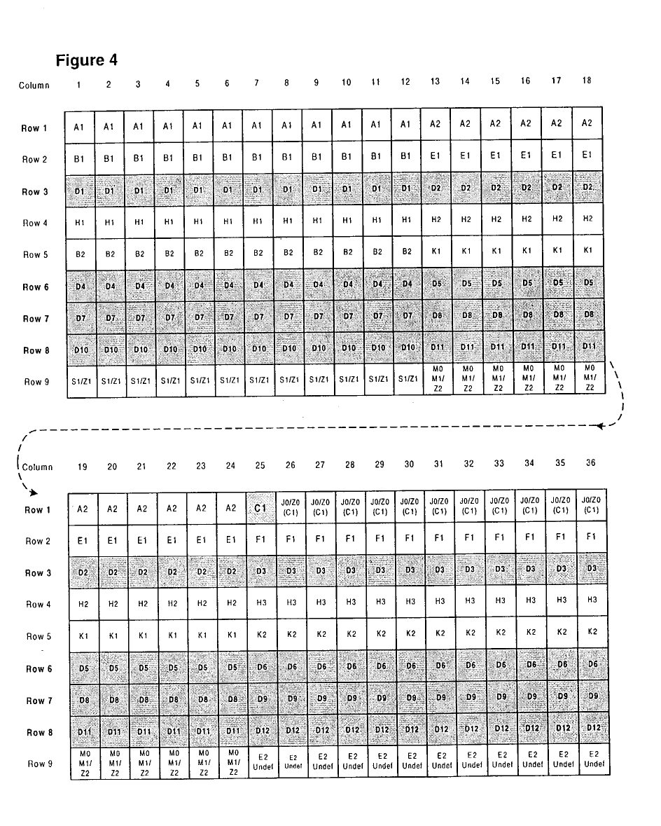

Data Communication Channel (DCC) is an AT&T SONET term used to describe a channel contained within the overhead bytes and used as an embedded operations channel to communicate to each network element. The DCC bytes in the SONET transport overhead are used to send and receive in-band messages between devices. In the present invention the messages are used to send CMP selection information. Each message is 36 bytes long and 4 messages can be sent each frame. The messages are transmitted during rows 3, 6, 7 and 8. The same bytes are used for both telecom bus and interconnect bus formats and are shown in grey in FIG. 4.

In-Band Link Format

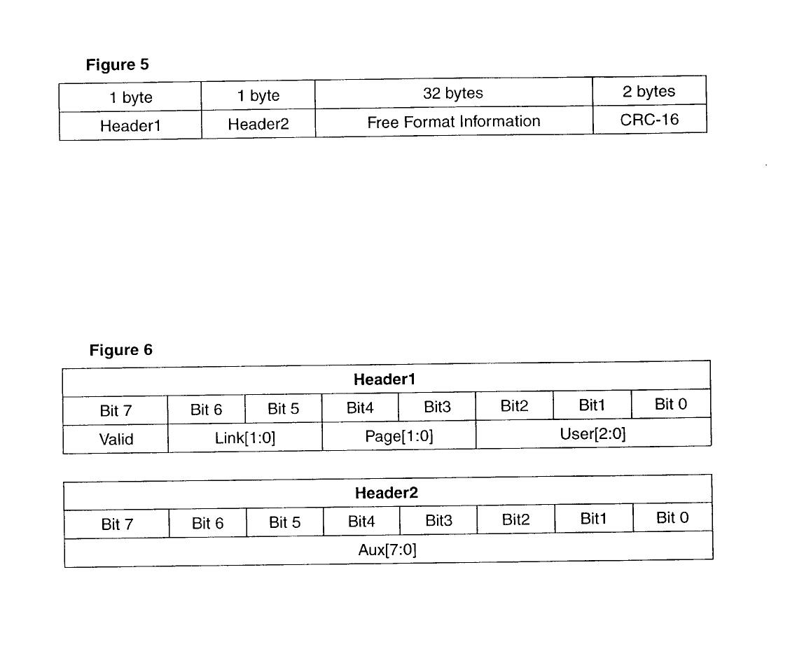

The format of the in-band message is shown in FIGS. 5 & 6. A brief description of each of the bits in the two header bytes is shown in Table 1. In the illustrative embodiment, each in-band message contains 2 header bytes, 32 bytes containing the free format information, and 2 bytes for a CRC-16. The free format bytes are used to provide a clear channel between the processor 50 connected to the space switch 20 and the time switches 30. With respect to switch fabrics in general, each time and space switch device making up a switch fabric will have a processor attached to it to handle configuration and to monitor status. These processors will likely receive the free format bytes. In the present illustrative embodiment only the processor 50 connected to the space switch 20 is explicitly identified and discussed because it is the only one directly involved in the performance of the page swaps. Nevertheless, the free format bytes can be used for communication between the various processors connected to the time and space switch devices (which are potentially located on different cards or shelves).

CRC is an error-checking technique that uses a calculated numeric value to detect errors in transmitted data. The sender of a data frame calculates the Frame Check Sequence (FCS). The sender appends the FCS value to outgoing messages. The receiver recalculates the FCS and compares it to the FCS from the sender. If a difference exists, the receiver assumes that a transmission error occurred, and sends a request to the sender to resend the frame.

TABLE 1
In-band Message Header Fields

| | From space switch to | From time switch to |
|---|---|---|
| Field Name | time switch | space switch |
| Valid | Message slot contains | Message slot contains |
| | a valid message(1) or | a valid message(1) or |
| | is empty(0) If | is empty(0) If |
| | empty this message | empty this message |
| | will not be put into | will not be put into |
| | Rx Message FIFO | Rx Message FIFO |
| | (other header | (other header |
| | information processed | information processed |
| | as usual) | as usual) |
| Link[1:0] | Each bit indicates | Each bit shows |
| | which Link to use, | current Link in use, |
| | working(0) or | working(0) or |
| | Protect(1). | Protect(1). |
| | Changes to these bits | Changes to these bits |
| | are transmitted at | are transmitted at |
| | the next opportunity. | the next opportunity. |
| Page[1:0] | Each bit indicates | Each bit shows |
| | which configuration | current control page |
| | page to use, page 1 | in use, page 1 or |
| | or page 0, for the | page 0, for the |
| | corresponding CMP. | corresponding CMP. |
| | Page[1] controls the | Page[1] indicates the |
| | CMP configuration | CMP configuration |
| | page of the input | page of the input |
| | time switch and | time switch and |
| | Page[0] controls the | Page[0] indicates the |
| | CMP configuration | CMP configuration |
| | page of the output | page of the output |
| | time switch. Changes | time switch. Changes |
| | to these bits are | to these bits are |
| | only transmitted from | only transmitted from |
| | the beginning of the | the beginning of the |
| | first message of the | first message of the |
| | frame. | frame. |
| User[2:0] | User defined bits | User defined bits. |
| | which may be read | User[2] is sourced |
| | through the | from the IUSER2 input |
| | microprocessor | to the time switch. |
| | interface. User[2] | User[1:0] is sourced |
| | is also output from | from an internal |
| | the time switch on | register. |
| | the OUSER2 pin, | changes to these bits |
| | Changes to these bits | are transmitted at |
| | are transmitted at | the next opportunity. |
| | the next opportunity. | |
| Aux[7:0] | User defined | User defined |
| | auxiliary register | auxiliary register |
| | indication. | indication. |
| | Changes to these bits | Changes to these bits |
| | are transmitted at | are transmitted at |
| | the next opportunity. | the next opportunity. |

Changes in the Link[1:0], Page [1:0], User [2:0] and Aux [7:0] bits (receive side) will not be processed if the received message CRC-16 indicates an error.

As each message arrives, the CRC-16 and Valid bit is checked. If the valid bit is not set, the 32 byte free format information is discarded. If it fails the CRC check it is flagged as being in error and an interrupt is generated if enabled. If the CRC-16 is OK, regardless of the Valid bit, the Page, Link, User and Aux bits are passed on.

Synchronized Page Switches

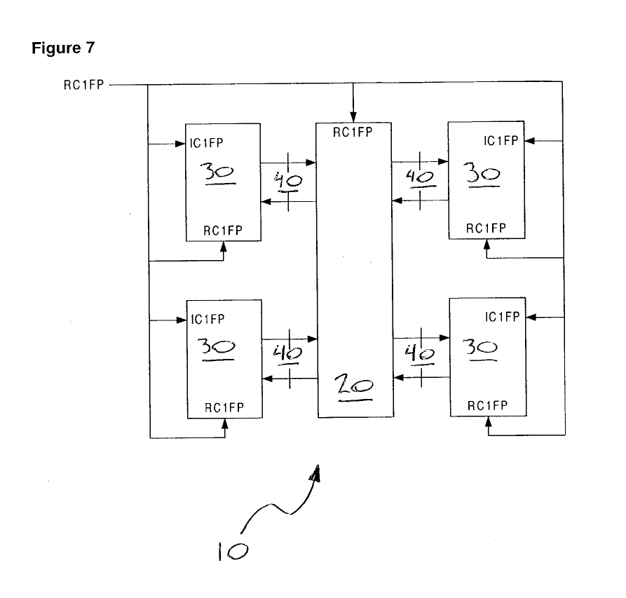

Switching between the two connection memory pages (CMP) in each device of the switch fabric must be synchronized. A common system frame pulse (RC1FP) is distributed to each device 20, 30 in the fabric and this frame pulse is used to synchronize the CMP changes. The frame pulse distribution for a fabric 10 consisting of 4 time switches 30 and 1 space switch 20 is shown in FIG. 7.

Referring to FIGS. 1 and 7, the CMP used by each device 20, 30 is only sampled during the RC1FP position. The CMP selection information is then delayed by the appropriate amount so that page changes are aligned to the start of the next frame or multiframe, depending on the mode. Synchronized page changes are achieved because each device 20, 30 changes its CMP at the same point in time relative to the data flowing through the device 20, 30.

The control of the CMP change synchronization is aided by the use of the in-band link. The PAGE[1:0] bits in the in-band link can be used to select the on-line CMP of the time switch devices 30. This allows the central processor 50 connected to the space switch device 20 to have control over the CMP that each time switch in the system is operating on. The control processor 50 can also program the CMP value of the space switch 30 by writing to a particular register in the space switch 20. Therefore, a CMP change can be initiated across the entire switch fabric 10 by only writing to the registers in the space switch 20.

When the off-line pages in all devices are ready, the following procedure should be used to perform a CMP switch:

1. The frame interrupt in the space switch 20 should be enabled. This will cause the space switch 20 to generate an interrupt on the C1 byte (see FIGS. 2, 3, 4) as marked by the RC1FP input. Note that RC1FP is the reference frame pulse used by all devices 20, 30 in the switch fabric 10.

2. Upon recognizing the frame interrupt, the PAGE bits (see Table 1 and FIGS. 5 and 6) to be sent to the time switch devices 30 must be written into the space switch registers before the first in-band link message of the frame is sent to the time switch devices 30. The time between the interrupt and the first message sent is approximately 40 s, therefore the control processor 50 must write to the registers in the space switch 20 within 40 s of receiving the interrupt.

3. The control processor 50 must then write the new PAGE bits for the space switch 20. This must be completed before the C1 position of the next frame. This will be approximately 125 s from when the frame interrupt was recognized.

4. The frame interrupt in the space switch 20 should be disabled.

5. All space switch 20 and time switch devices 30 will have received the new page bits before the C1 position of the next frame. Each device 20, 30 will sample the new PAGE bits on the C1 position and will perform the CMP change at the start of the following frame.

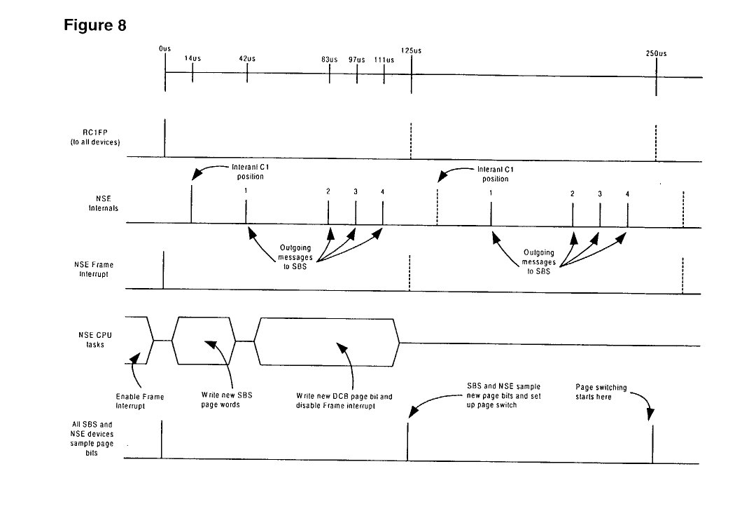

The procedure for initiating a CMP change in the system configured for telecom bus mode is illustrated in FIG. 8. Note that in telecom bus mode, the latency through the time switch devices 30 is approximately 1 row, or 14 s.

In-band link messages are sent from the space switch device 20 to the time switch devices 30 four times per frame. This provides protection of the PAGE bits against bit errors on the serial links 40. If there is a bit error during one of the messages in the frame, the CRC check will recognize this and the PAGE bits will not be updated. As long as one of the four messages in the frame has a correct CRC, the PAGE bits in the time switch devices 30 will be updated correctly and the CMP swap will be synchronized across the entire fabric 10.

While this invention has been described with reference to illustrative embodiments, this description is not intended to be construed in a limiting sense. Various modifications of the illustrative embodiments, as well as other embodiments of the invention, will be apparent to persons skilled in the art upon reference to this description. It is therefore contemplated that the appended claims will cover any such modifications or embodiments as fall within the true scope of the invention.

We claim:

1. A centrally synchronized distributed switch, comprising:
a) a control processor;
b) at least one space switch coupled to said control processor; and
c) at least one time switch coupled to said space switch by a serial link;
wherein each of said space switch and said time switch comprises an on-line configuration page and an off-line configuration page, and
wherein configuration page selection information generated by said control processor is sent to said time switch in-band over said serial link.

2. The switch according to claim 1, wherein said switch comprises two types of time switches, namely, input time switches and output time switches.

3. The switch according to claim 1, wherein said control processor sends a common system frame pulse to each one of said time and space switches.

4. The switch according to claim 3, wherein said configuration pages are sampled only during said common system frame pulse.

5. The switch according to claim 1, wherein said configuration page selection information is written into registers in said space switch before being sent to said time switches.

6. The switch of claim 1, wherein said configuration page selection information is CRC protected.

7. The switch of claim 6, wherein said configuration page selection information is disregarded if a CRC error is detected.

8. The switch of claim 1, wherein data on said serial links is 8B/10B encoded.

9. The switch of claim 1, wherein said configuration page selection information is sent to said time switches via dedicated overhead bytes.

10. A centrally synchronized distributed switch, comprising:
a) a control processor;
b) at least one space switch coupled to said control processor;
c) a plurality of input time switches each coupled to said space switch by a serial link; and
d) a plurality of output time switches each coupled to said space switch device by a serial link;
wherein each of said space switch, said input time switches and said output time switches comprises an on-line configuration page and an off-line configuration page, and
wherein configuration page selection information is sent to said input and output time switches in-band over said serial links.

11. A method of synchronizing a distributed switch having a control processor, at least one space switch coupled to said control processor, and a plurality of time switches each coupled to said space switch by a serial link, said method comprising sending configuration page selection information to said time switches in-band over said serial links.

12. The method according to claim 11, further comprising the following two steps, which are carried out prior to sending said configuration page selection information:
a) writing said configuration page selection information for said time switches to a register in said space switch; and
b) writing said configuration page selection information for said space switch.

13. The method according to claim 11, further comprising the following two steps, which are carried out prior to writing said configuration page selection information for said time switches to said register:
a) generating a common system frame pulse;
b) enabling a frame interrupt in said space switch; and
c) generating a frame interrupt on said common system frame pulse.

14. The method according to claim 13, further comprising the following step, which is carried out after said configuration page selection information is sent to said time switches:
a) disabling said frame interrupt.

15. A method of synchronizing a switch defined in claim 1, comprising sending said configuration page selection information to said time switches in-band over said serial links.

16. The method of claim 15, further comprising the following two steps, which are carried out prior to sending said configuration page selection information to said time switches:
a) writing configuration page selection information for said time switches to a register in said space switch; and
b) writing configuration page selection information for said space switch.

17. The method according to claim 16, further comprising the following two steps, which are carried out prior to writing said configuration page selection information for said time switches to said register:
a) generating a common system frame pulse;
b) enabling a frame interrupt in said space switch; and
c) generating a frame interrupt on said common system frame pulse.

18. The method according to claim 17, further comprising the following step, which is carried out after said configuration page selection information is sent to said time switches:
a) disabling said frame interrupt.
